(19) United States
(12) Patent Application Publication
(10) Pub. No.: US 2023/0135672 A1
(43) Pub. Date: May 4, 2023

(54) LIGHT-EMITTING DEVICE

(71) Applicant: SHARP KABUSHIKI KAISHA, Sakai City, Osaka (JP)

(72) Inventor: TAZUKO KITAZAWA, Sakai City, Osaka (JP)

(21) Appl. No.: 17/912,495

(22) PCT Filed: Apr. 28, 2020
(86) PCT No.: PCT/JP2020/018180

§ 371 Date: Sep. 17, 2022

(51) Int. Cl. H10K 50/86; H10K 59/35

(52) U.S. Cl. CPC H01L 51/5284; H01L 27/3211; H01L 51/502

(57) ABSTRACT

A light-emitting device, includes: a substrate transparent to light a first light-emitting layer provided above the substrate and containing first quantum dots configured to emit a first light a second light-emitting layer provided above the substrate and configured to emit a second light shorter in wavelength than the first light a pair of first color-correcting layers each correspondingly provided to one of above or below the first light-emitting layer to overlap with at least a portion of the first light-emitting layer in plan view, transmitting the first light, and absorbing light shorter in wavelength than the first light and a pair of second color-correcting layers each correspondingly provided to one of above or below the second light-emitting layer to overlap with the second light-emitting layer in plan view, transmitting the second light, and absorbing light longer in wavelength than the second light.

### TECHNICAL FIELD

The disclosure relates to a light-emitting device.

### BACKGROUND ART

Patent Document 1 discloses a transmissive display device.

### CITATION LIST

### Patent Literature

[Patent Document 1] Japanese Unexamined Patent Application Publication No. 2018-189937 (Published on Nov. 29, 2018)

### SUMMARY

### Technical Problem

Regarding the transmissive light-emitting device disclosed in Patent Document 1, a light-emitting material of a light-emitting layer included in the light-emitting device would be unexpectedly excited by background light. Hence, even if no light is emitted, the light-emitting face of the light-emitting device might appear yellowish.

### Solution to Problem

In order to solve the above problem, A light-emitting device according to an aspect of the disclosure includes: a substrate transparent to light; a first light-emitting layer provided above the substrate and containing first quantum dots that emit a first light; a second light-emitting layer provided above the substrate and emitting a second light shorter in wavelength than the first light; a pair of first color-correcting layers each correspondingly provided to one of above or below the first light-emitting layer to overlap with at least a portion of the first light-emitting layer in plan view, transmitting the first light, and absorbing light shorter in wavelength than the first light; and a pair of second color-correcting layers each correspondingly provided to one of above or below the second light-emitting layer to overlap with the second light-emitting layer in plan view, transmitting the second light, and absorbing light longer in wavelength than the second light.

### Advantageous Effects of Disclosure

An aspect of disclosure can provide a transmissive light-emitting device that keeps the light-emitting surface from appearing yellowish by background light.

### BRIEF DESCRIPTION OF DRAWINGS

FIG. 1 is a cross-sectional view of a light-emitting device according to a first embodiment.

FIG. 2 is a graph showing transmission spectra of first color-correcting layers and second color-correcting layers provided to the above light-emitting device.

FIG. 3 is a graph showing spectra observed when the above first and second color-correcting layers are applied to the configuration illustrated in FIG. 1 if background light is LED light.

FIG. 4 is a graph showing spectra observed when the above first and second color-correcting layers are applied to the configuration illustrated in FIG. 1 if background light is sun light.

FIG. 5 is a cross-sectional view of a light-emitting device according to a second embodiment.

FIG. 6 is a cross-sectional view of a light-emitting device according to a third embodiment.

FIG. 7 is a graph showing transmission spectra of first, second and third color-correcting layers provided to the above light-emitting device.

FIG. 8 is a graph showing spectra observed when the above first, second, and third color-correcting layers are applied to the configuration illustrated in FIG. 6 if background light is sun light.

FIG. 9 is a chromaticity diagram plotting the above spectra.

FIG. 10 is a cross-sectional view of a light-emitting device according to a fourth embodiment.

### DESCRIPTION OF EMBODIMENTS

In this DESCRIPTION, an “absorption edge” of quantum dots means a wavelength corresponding to an energy bandgap of the quantum dot material.

### First Embodiment

Light emitted in this embodiment is classified into a first light and a second light. The second light is shorter in wavelength than the first light. Moreover, a light-emitting layer is classified into: a first light-emitting layer that emits the first light; and a second light-emitting layer that emits the second light. Furthermore, quantum dots contained in the light-emitting layer are classified into: first quantum dots contained in the first light-emitting layer; and second quantum dots contained in the second light-emitting layer. The same applies to a second embodiment and the following embodiments to be described later.

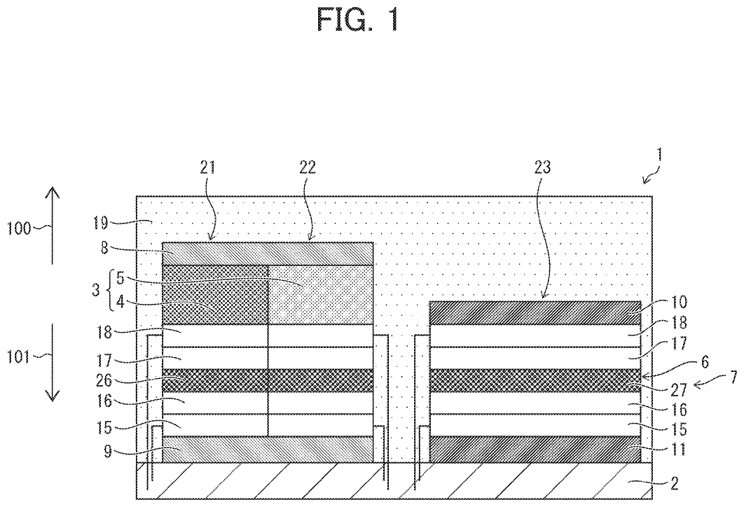

FIG. 1 is a cross-sectional view of a light-emitting device 1 according to a first embodiment. The light-emitting device 1 includes: a substrate 2 transparent to light; a red light-emitting element 21 that emits a red light (the first light); a green light-emitting element 22 that emits a green light (the first light); and a blue light-emitting element 23 that emits a blue light (the second light). All of the red, green, and blue light-emitting elements 21, 22, and 23 are formed on the substrate 2.

The red light-emitting element 21 includes: a red light-emitting layer 4 (a first light-emitting layer 3) containing red quantum dots (first quantum dots) that emit the red light; a pair of first color-correcting layers 8 and 9 respectively provided above and below the red light-emitting layer 4 to overlap with the red light-emitting layer 4 in plan view; and a first blue light-emitting portion 26 sandwiched between the red light-emitting layer 4 and the first color-correcting layer 9, and included in a blue light-emitting layer 7 (a second light-emitting layer 6) that emits a blue light. Note that the first color-correcting layers 8 and 9 transmit the red light and the green light.

Here, the term “above” means a direction away from the substrate 2 and the term “below” means a direction toward the substrate 2. The terms mean the directions of the respective arrows 100 and 101 illustrated in FIG. 1.

The green light-emitting element 22 includes: a green light-emitting layer 5 (the first light-emitting layer 3) containing green quantum dots (the first quantum dots) that emit the green light; a pair of the first color-correcting layers 8 and 9 respectively provided above and below the green light-emitting layer 5 to overlap with the green light-emitting layer 5 in plan view; and the first blue light-emitting portion 26 sandwiched between the green light-emitting layer 5 and the first color-correcting layer 9, and included in the blue light-emitting layer 7 (the second light-emitting layer 6) that emits the blue light. The first color-correcting layers 8 and 9 may be shared between the red light-emitting element 21 and the green light-emitting element 22 as illustrated in FIG. 1. Note that, preferably, the green light-emitting layer 5 does not overlap with, and is separated from, the red light-emitting layer 4 with, for example, a bank not shown in FIG. 1.

The blue light-emitting element 23 includes: a second blue light-emitting portion 27 of the blue light-emitting layer 7 (the second light-emitting layer 6) containing blue quantum dots (the second quantum dots) that emit the blue light; and a pair of second color-correcting layers 10 and 11 respectively provided above and below the second blue light-emitting portion 27, and overlapping with the second blue light-emitting portion 27 of the blue light-emitting layer 7 in plan view. Note that the second color-correcting layers 10 and 11 transmit the blue light and absorb a yellow light. The blue light-emitting layer 7 emits light with, for example, the blue quantum dots. However, the disclosure shall not be limited to such an example. The blue light-emitting layer 7 may emit light with an organic material.

The blue light-emitting layer 7 includes: the first blue light-emitting portion 26 formed in a position to overlap with the first color-correcting layers 8 and 9 in plan view; and the second blue light-emitting portion 27 formed in a position to overlap with the second color-correcting layers 10 and 11 in plan view. The blue light-emitting layer 7 includes, for example, the first blue light-emitting portion 26 and the second blue light-emitting portion 27 separately formed from each other. However, the disclosure shall not be limited to such an example. The first blue light-emitting portion 26 and the second blue light-emitting portion 27 may be formed in a single piece in common between the first color-correcting layers 8 and 9 and the second color-correcting layers 10 and 11. As can be seen, the blue light-emitting layer 7 may have the first blue-light emitting portion 26 and the second blue light-emitting portion 27 formed separately from each other so that the first blue light-emitting portion 26 is positioned to overlap with the first light-emitting layer 3 in plan view and the second blue light-emitting portion 27 is positioned not to overlap with the first light-emitting layer 3 in plan view. Alternatively, the blue light-emitting layer 7 may be formed continuously from a position to overlap with the first light-emitting layer 3 in plan view to a position not to overlap with the first light-emitting layer 3 in plan view.

The blue light-emitting layer 7 emits light by electroluminescence (EL). The red light-emitting layer 4 and the green light-emitting layer 5 emit light by photoluminescence (PL) based on the blue light emitted from the first blue light-emitting portion 26 included in the blue light-emitting layer 7 and overlapping with each of the red light-emitting layer 4 and the green light-emitting layer 5.

The first blue light-emitting portion 26 of the blue light-emitting layer 7 is provided to overlap with the red light-emitting layer 4 and the green light-emitting layer 5.

The first color-correcting layers 8 and 9 transmit the red light emitted from the red light-emitting layer 4 and the green light emitted from the green light-emitting layer 5, and absorb the blue light emitted toward the red light-emitting layer 4 and the blue light emitted toward the green light-emitting layer 5.

That is, the first color-correcting layers 8 and 9 preferably absorb light a wavelength of which is shorter than an absorption edge of the second quantum dots (the blue quantum dots).

The first color-correcting layers 8 and 9 preferably absorb light having a wavelength of 530 nm or less. Hence, the first color-correcting layers 8 and 9 can absorb light a wavelength of which is shorter than that of the green light, making it possible to reduce unexpected light to be emitted from the red light-emitting layer 4 emitting the red light and from the green light-emitting layer 5 emitting the green light.

In plan view, the first color-correcting layers 8 and 9 are preferably equal in area to the second color-correcting layers 10 and 11. Such a feature provides better white balance to the background light when no light is emitted.

Moreover, in plan view, the second light-emitting layer 6 overlapping with the second color-correcting layers 10 and 11 is preferably equal in area to the second color-correcting layers 10 and 11. Such a feature simplifies the configuration of the light-emitting device 1. Furthermore, the feature can increase the area of the blue light-emitting layer 7 emitting a blue light whose emission efficiency is typically low. Hence, a current injection density of the blue light-emitting layer 7 can be reduced lower than that of the blue light-emitting layer 7 in a regular size. The reduced current injection density can increase the life of the blue light-emitting layer 7 that emits the blue light.

Each of the red light-emitting layer 4 and the green light-emitting layer 5 emits light by light excitation. Each of the red light-emitting layer 4 and the green light-emitting layer 5 overlaps in plan view with the first blue light-emitting portion 26 of the blue light-emitting layer 7, and emits light by light excitation of the light emitted from the first blue light-emitting portion 26 of the blue light-emitting layer 7.

The first light-emitting layer 3 emits the red light and the green light (the first light) in a direction toward the substrate 2 and a direction away from the substrate 2. The second light-emitting layer 6 emits the blue light (the second light) in the direction toward the substrate 2 and the direction away from the substrate 2. That is, the red light-emitting layer 4 of the first light-emitting layer 3 emits the red light upwards and downwards, and the green light-emitting layer 5 of the first light-emitting layer 3 emits the green light upwards and downwards. Then, the blue light-emitting layer 7 of the second light-emitting layer 6 emits the blue light upwards and downwards.

The blue light-emitting element 23 includes: the second color-correcting layer 11; a first electrode 15; an electron-transport layer 16; the second blue light-emitting portion 27 of the blue light-emitting layer 7; a hole-transport layer 17; a second electrode 18; and the second color-correcting layer 10, all of which are stacked one another on the substrate 2 in this order. The red light-emitting element 21 and the green light-emitting element 22 each include: the first color-correcting layer 9; the first electrode 15; the electron-transport layer 16; the first blue light-emitting portion 26 of the blue light-emitting layer 7; the hole-transport layer 17; and the second electrode 18, all of which are stacked one another on the substrate 2 in this order. Then, on the second electrode 18, the red light-emitting layer 4 and the green light-emitting layer 5 are stacked.

Next, on the red light-emitting layer 4 and the green light-emitting layer 5, the first color-correcting layer 8 is stacked.

The EL emits only the blue light out of the red light, the green light, and the blue light. Hence, the first electrode 15, the second electrode 18, the electron-transport layer (ETL) 16, and the hole-transport layer (HTL) 17 are required only of one set for emitting the blue light only. Such a feature simplifies the configuration of, and facilitates the production of, the light-emitting device 1.

Note that the red light-emitting layer 4 that emits the red light and the green light-emitting layer 5 that emits the green light may emit the lights by EL. Also, in such a case, the red light-emitting layer 4 and the green light-emitting layer 5 contain the first quantum dots.

Note that the first quantum dots of this embodiment can be made of CdSe. If the light is emitted in different colors (wavelengths) such as red and green, the size of the first quantum dots may be optimized. The second quantum dots can be made of CdZnSe. Such a feature can provide the light-emitting layer with high efficiency at a low cost. Note that the first quantum dots and the second quantum dots may contain one or more semiconductor materials selected from a group including, for example, such elements as Cd, S, Te, Se, Zn, In, N, P, As, Sb, Al, Ga, Pb, Si, Ge, and Mg, or a composition of these elements. Moreover, the first quantum dots and the second quantum dots may be in a two-component-core structure, a three-component-core structure, a four-component-core structure, a core-shell structure, or a core-multishell structure.

As to the light-emitting device 1, such constituent features as the substrate 2, the first electrode 15, and the second electrode 18 are transparent. The light-emitting device 1 is applicable to a transparent display.

In order to provide each of the layers with insulation and wiring, a protective layer 19 appropriately shaped is provided between and around the layers. A partition wall is provided to separate the red light-emitting layer 4 from the green light-emitting layer 5, and the green light-emitting layer 5 from the blue light-emitting layer 7. FIG. 1 omits an illustration of the partition walls.

The first electrode 15, the second electrode 18, the electron-transport layer 16, the hole-transport layer 17, and the protective layer 19 can be made of a material usually used for an organic light-emitting diode (OLED) and a quantum-dot light-emitting diode (QLED).

The first electrode 15 and the second electrode 18 may be made of such a material as, for example, ITO, IZO, AZO, or GZO, and deposited by such a technique as sputtering.

The electron-transport layer 16 may contain such a material as, for example, ZnO, MgZnO, TiO₂, Ta₂O₃, or SrTiO₃. Alternatively, the electron-transport layer 16 may contain two or more of these materials.

The hole-transport layer 17 may have a function to block transportation of the electrons. The hole-transport layer 17 may contain such a material as, for example, PEDOT:PSS, PVK, TFB, or poly-TPD. Alternatively, the hole-transport layer 17 may contain two or more of these materials.

Using these materials, the electrodes and the transport layers can be formed to be transparent with excellent electric characteristics, by such a simple technique as sputtering or coating.

A transparent pixel may separately be provided to increase a transmittance of the background light. Note that the transparent pixel may be formed of such a material as, for example, SiN, Sift, or transparent resin to be used for a transparent protective layer.

As can be seen, in order to prevent PL light emission, of the red light-emitting layer 4 and the green light-emitting layer 5, due to the background light of the first quantum dots, the first color-correcting layers 8 and 9 are respectively provided above and below the red light-emitting layer 4 and the green light-emitting layer 5 (the first light-emitting layer 3) to absorb the blue light of the background light. Then, the white balance obtained by the absorption of the blue light is corrected with the second color-correcting layers 10 and 11 respectively provided above and below the second blue light-emitting portion 27 of the blue light-emitting layer 7 to absorb the yellow light of the background light.

There is a known problem as follows. That is, in a case of a QLED, the red light-emitting layer 4 (the first light-emitting layer 3) that emits the red light and the green light-emitting layer 5 (the first light-emitting layer 3) that emits the green light contain the first quantum dots absorbing background light toward higher energy in relation to the respective emission wavelengths of the red light-emitting layer 4 and the green light-emitting layer 5. Then, thanks to this background light acting as excitation light, the PL light emission occurs to the red light-emitting layer 4 and the green light-emitting layer 5 (the first light-emitting layer 3). This PL light emission causes a problem; that is, if the light-emitting device 1 is used for a transparent display, the transparent display appears yellowish when no light is emitted.

In contrast, in this embodiment, the first color-correcting layers 8 and 9 absorb the blue light of the background light travelling toward the red light-emitting layer 4 and the green light-emitting layer 5 (the first light-emitting layer 3), thereby preventing the PL light emission to be caused, by the background light, to the red light-emitting layer 4 and the green light-emitting layer 5 (the first light-emitting layer 3).

Then, the second color-correcting layers 10 and 11 can maintain a color tone of the background light in balance.

In order to prevent the PL light emission of the red light-emitting layer 4 that emits the red light and of the green light-emitting layer 5 that emits the green light, the first color-correcting layers 8 and 9 preferably absorb all the wavelengths less than the absorption edge of the first quantum dots in the first light-emitting layer 3. If the first light-emitting layer 3 and the first quantum dots include a plurality of kinds of the first light-emitting layers 3 and the first quantum dots, the absorption edge is the one with the shortest wavelength. If the first light-emitting layer 3 includes the red light-emitting layer 4 and the green light-emitting layer 5, a wavelength less than this absorption edge is specifically 530 nm or less.

If an ultraviolet range is cut with the protective layer 19 or with a layer other than the protective layer 19, the first color-correcting layers 8 and 9 may cut and absorb a wavelength more than, or equal to, the wavelength of the ultraviolet range.

The first color-correcting layers 8 and 9 may be typical wavelength filters.

The second color-correcting layers 10 and 11 are respectively formed above an upper face and below a lower face of the second blue light-emitting portion 27 of the blue light-emitting layer 7 including a pixel that emits the blue light. The second color-correcting layers 10 and 11 absorb the yellow light. If provided are the first color-correcting layers 8 and 9 alone, the background light from outside appears yellowish. That is why the second color-correcting layers 10 and 11 are provided to adjust the white balance of this background light.

Hence, the second color-correcting layers 10 and 11 preferably absorb all the wavelength ranges that are included in a visible range and not cut with the first color-correcting layers 8 and 9. The second color-correcting layers 10 and 11 may be typical wavelength filters.

In FIG. 1, the first color-correcting layer 8 and the second color-correcting layer 10 above the blue light-emitting layer 7 are provided to handle the background light traveling toward the red light-emitting layer 4, the green light-emitting layer 5, and the second blue light-emitting portion 27 of the blue light-emitting layer 7 from an opposite side of the substrate 2.

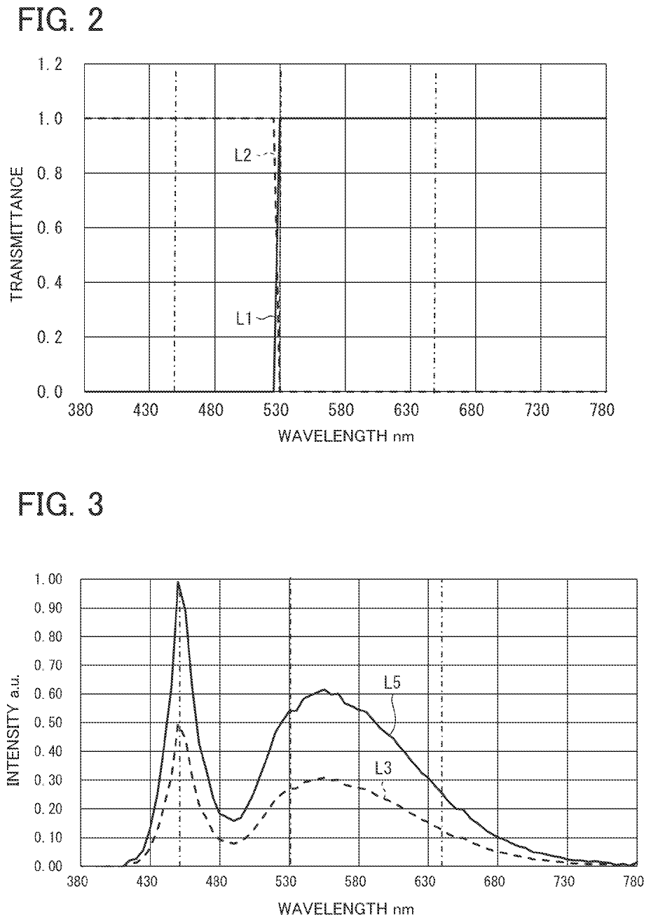

FIG. 2 is a graph showing transmission spectra of the first color-correcting layers 8 and 9 and the second color-correcting layers 10 and 11 provided to the light-emitting device 1. As a line L1 shows, the first color-correcting layers 8 and 9 absorb and cut light having a wavelength of 530 nm or less. Then, as a line L2 shows, the second color-correcting layers 10 and 11 absorb and cut light having a wavelength of 530 nm or more.

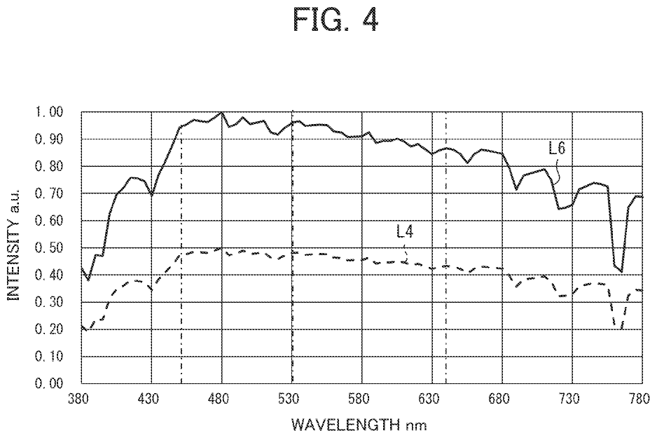

FIG. 3 is a graph showing spectra observed when the first color-correcting layers 8 and 9 and the second color-correcting layers 10 and 11 are applied to the configuration illustrated in FIG. 1 if the background light is LED light. FIG. 4 is a graph showing spectra observed when the first color-correcting layers 8 and 9 and the second color-correcting layers 10 and 11 are applied to the configuration illustrated in FIG. 1 if the background light is sun light.

In FIG. 3, a line L5 shows a relationship between the wavelength and the intensity of the LED light incident on the first color-correcting layers 8 and 9 and on the second color-correcting layers 10 and 11. A line L3 shows a relationship between the wavelength and the intensity of the LED light transmitted through the first color-correcting layers 8 and 9 and the second color-correcting layers 10 and 11.

In FIG. 4, a line L6 shows a relationship between the wavelength and the intensity of the sun light incident on the first color-correcting layers 8 and 9 and on the second color-correcting layers 10 and 11. A line L4 shows a relationship between the wavelength and the intensity of the sun light transmitted through the first color-correcting layers 8 and 9 and the second color-correcting layers 10 and 11.

In FIG. 3, the spectrum in the line L3 of the LED light transmitted through the first color-correcting layers 8 and 9 and the second color-correcting layers 10 and 11 is just as half as the spectrum in the line L5 of the LED light. Moreover, in FIG. 4, the spectrum in the line L4 of the sun light transmitted through the first color-correcting layers 8 and 9 and the second color-correcting layers 10 and 11 are just as half as the spectrum in the line L6 of the sun light.

This is because the first color-correcting layers 8 and 9 and the second color-correcting layers 10 and 11 are formed to have the same area. Besides, the first color-correcting layers 8 and 9 and the second color-correcting layers 10 and 11 are formed to have the transmittance set to 0 for a wavelength range in which light is absorbed, and to 1 for the other wavelength ranges.

Hence, on a QLED display including the light-emitting device 1 according this embodiment, the color tone of the background light does not vary.

If the areas of the second color-correcting layers 10 and 11 are different from the areas of the first color-correcting layers 8 and 9, the color tone of the background light varies before and after the background light is transmitted through the first color-correcting layers 8 and 9 and the second color-correcting layers 10 and 11. If the color tone varies to the degree that the white balance does not significantly vary, the areas of the second color-correcting layers 10 and 11 may be different from the areas of the first color-correcting layers 8 and 9. Alternatively, according to an area ratio of the second color-correcting layers 10 and 11 to the first color-correcting layers 8 and 9, the absorptivity of the second color-correcting layers 10 and 11 may be changed. The first color-correcting layers 8 and 9 has to have an absorptivity of substantially 100% in order to cut a blue excitation light. However, the absorptivity of the second color-correcting layers 10 and 11 can be changed.

The intensity of the background light after the transmission falls to one half before the transmission. The same is true on a configuration in which a transmission region and a pixel region (not-transparent) are separated from each other. If the intensity of the background light after the transmission may be low, a transparent pixel may separately be provided to raise the transmittance of the background light.

In the case of the configuration in which the transmission region and the pixel region (not transparent) are separated from each other, the display cannot be a double-sided display. However, in this embodiment, the transmission region and the pixel region (not transparent) can be separated from each other.

Note that the example in FIG. 1 shows a case where the red light-emitting layer 4 and the green light-emitting layer 5 are arranged across the blue light-emitting layer 7 from the substrate 2. However, the disclosure shall not be limited to such an example. The red light-emitting layer 4 and the green light-emitting layer 5 may be arranged toward the substrate 2 with respect to the blue light-emitting layer 7. Alternatively, the red light-emitting layer 4 and the green light-emitting layer 5 may arranged both across the blue light-emitting layer 7 from the substrate 2 and closer to the substrate 2 with respect to the blue light-emitting layer 7. The same is true on the embodiments to be described later.

### Second Embodiment

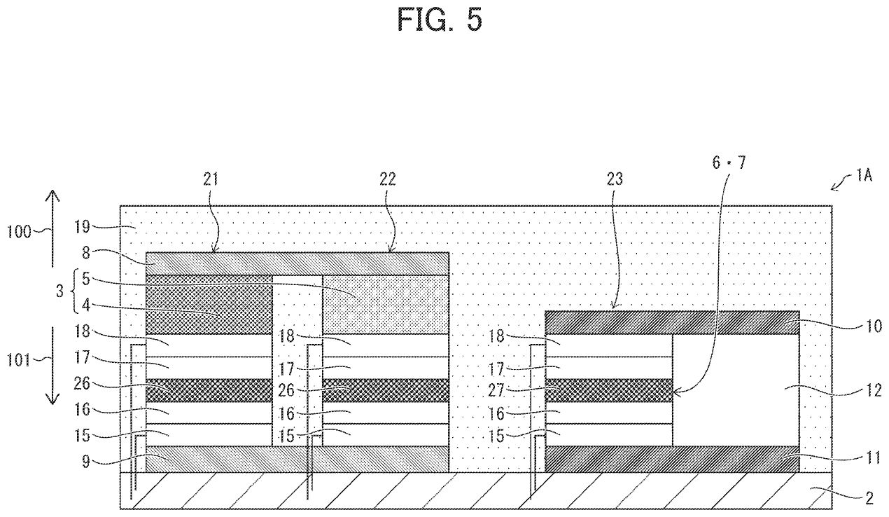

FIG. 5 is a cross-sectional view of a light-emitting device 1A according to a second embodiment. Like reference signs denote identical or corresponding constituent features between this embodiment and the previous embodiment. Details of such constituent features will not be elaborated upon here.

The light-emitting device 1A further includes a transparent buffer layer 12 provided above the substrate 2 and disposed side by side with the second light-emitting layer 6 in plan view. The transparent buffer layer 12 of this embodiment can be made of SiN, SiO₂, or transparent resin. Note that the transparent buffer layer 12 may be made of a material to be used for another transparent protective layer. The second color-correcting layers 10 and 11 are provided to overlap with the second light-emitting layer 6 and the transparent buffer layer 12 in plan view. The transparent buffer layer 12 is formed in approximately half a region of the second color-correcting layers 10 and 11.

In plan view, the second color-correcting layers 10 and 11 are larger in area than the second light-emitting layer 6 overlapping with the second color-correcting layers 10 and 11.

Such a feature can achieve the advantageous effects of the first embodiment. In addition, compared with the first embodiment, the feature can reduce the materials for the second quantum dots in the second light-emitting layer 6.

### Third Embodiment

In this third embodiment, the green quantum dots classified as the first quantum dots in the first and second embodiments are classified as third quantum dots, and distinguished from the first quantum dots of the red quantum dots.

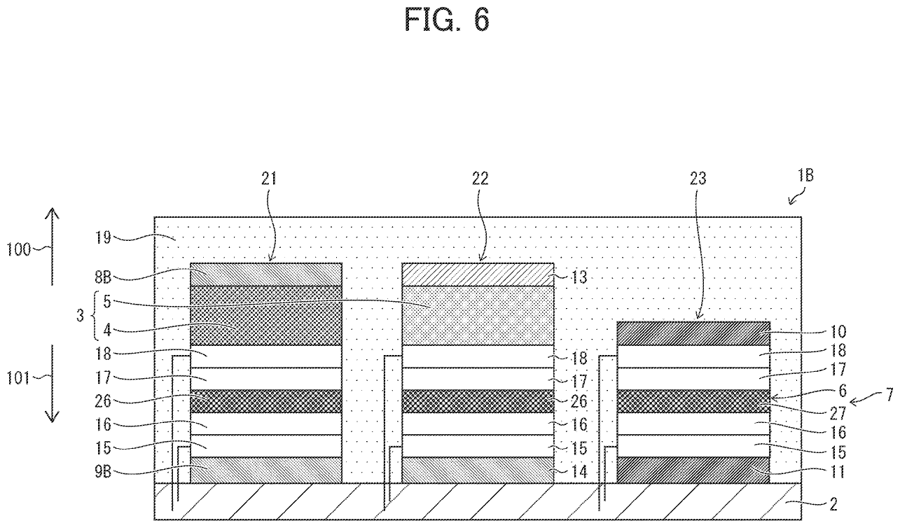

FIG. 6 is a cross-sectional view of a light-emitting device 1B according to the third embodiment. Like reference signs denote identical or corresponding constituent features between this embodiment and the previous embodiments. Details of such constituent features will not be elaborated upon here.

The light-emitting device 1B further includes at least two third color-correcting layers 13 and 14 that are different in characteristics from first color-correcting layers 8B and 9B and the second color-correcting layers 10 and 11.

A pair of the first color-correcting layers 8B and 9B overlaps only with the red light-emitting layer 4, transmits a red light emitted from the red light-emitting layer 4, and absorbs light shorter in wavelength than the red light.

The third color-correcting layers 13 and 14 are respectively provided above and below the green light-emitting layer 5, and overlap only with the green light-emitting layer 5 in plan view. Third color-correcting layers 13 and 14 transmit a green light emitted from the green light-emitting layer 5, and absorb light shorter in wavelength than the green light.

Hence, the light-emitting device 1B includes: the red light-emitting layer 4 provided between the pair of first color-correcting layers 8B and 9B, and overlapping with the first color-correcting layers 8B and 9B in plan view; and the green light-emitting layer 5 provided between the third color-correcting layers 13 and 14, and overlapping with the third color-correcting layers 13 and 14 in plan view.

The third color-correcting layers 13 and 14 absorb light a wavelength of which is shorter than an absorption edge of the third quantum dots. Such feature can reduce a tinge of the light-emitting device 1B more efficiently.

The third color-correcting layers 13 and 14 absorb light having a wavelength of 530 nm or less. Hence, the third color-correcting layers 13 and 14 can absorb the light a wavelength of which is shorter than, or equal to, that of the green light, thereby reducing light to be unexpectedly emitted from the green light-emitting layer 5 that emits the green light.

The first color-correcting layers 8 and 9 described in the first and second embodiments transmit a red light and a green light, and absorb light shorter in wavelength than the green light. In contrast, the first color-correcting layers 8B and 9B according to the third embodiment transmit the red light, and absorb light shorter in wavelength than the red light. The absorbed light has a wavelength less than 630 nm. Hence, the first color-correcting layers 8B and 9B can absorb the light a wavelength of which is shorter than that of the red light, thereby reducing light to be unexpectedly emitted from the red light-emitting layer 4 that emits the red light.

Then, the first color-correcting layers 8 and 9 absorb light a wavelength of which is shorter than that of the green light, thereby reducing both of the lights; that is, the light to be unexpectedly emitted from the green light-emitting layer 5 that emits the green light and the light to be unexpectedly emitted from the red light-emitting layer 4 that emits the red light.

As can be seen, the first color-correcting layers 8 and 9 and 8B and 9B transmit the first light (the red light and the green light), and absorb light shorter in wavelength than this first light.

Each of the first color-correcting layers 8B and 9B, the second color-correcting layers 10 and 11, and the third color-correcting layers 13 and 14 is preferably a color filter.

The first color-correcting layers 8B and 9B are respectively disposed above and below the red light-emitting layer 4 emitting the red light, and transmit only the red light but not the blue light. The second color-correcting layers 10 and 11 are respectively disposed above and below the second blue light-emitting portion 27 of the blue light-emitting layer 7 that emits the blue light, and transmit only the blue light. The third color-correcting layers 13 and 14 are respectively disposed above and below the green light-emitting layer 5 that emits the green light, and transmit only the green light but not the blue light.

These first color-correcting layers 8B and 9B, the second color-correcting layers 10 and 11, and the third color-correcting layers 13 and 14 may be typical color filters, and thus are inexpensive.

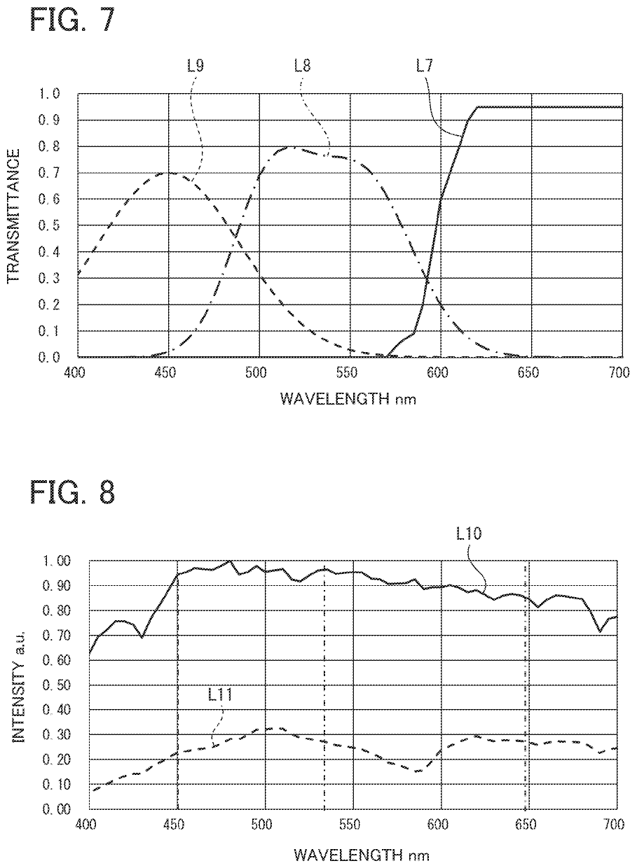

FIG. 7 is a graph showing transmission spectra of the first color-correcting layers 8B and 9B, the second color-correcting layers 10 and 11, and the third color-correcting layers 13 and 14 provided to the light-emitting device 1B. A line L7 shows a transmission spectrum of the first color-correcting layers 8B and 9B. A line L8 shows a transmission spectrum of the third color-correcting layers 13 and 14. A line L9 shows a transmission spectrum of the second color-correcting layers 10 and 11.

FIG. 8 is a graph showing spectra observed when the first color-correcting layers 8B and 9B, the second color-correcting layers 10 and 11, and the third color-correcting layers 13 and 14 are applied to the configuration illustrated in FIG. 6 if background light is sun light. In FIG. 8, a line L10 shows a relationship between the wavelength and the intensity of the sun light incident on the first color-correcting layers 8B and 9B, the second color-correcting layers 10 and 11, and the third color-correcting layers 13 and 14. A line L11 shows a relationship between the wavelength and the intensity of the sun light transmitted through the first color-correcting layers 8B and 9B, the second color-correcting layers 10 and 11, and the third color-correcting layers 13 and 14.

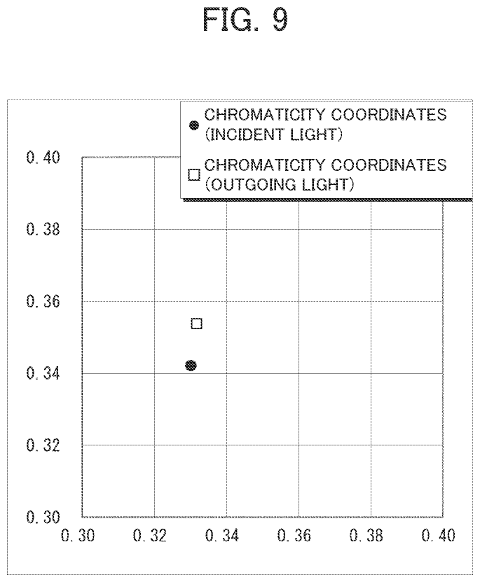

FIG. 9 is a chromaticity diagram plotting the above spectra. In FIG. 8, the spectrum represented by the line L11 and transmitted through color-correcting layers is different in wavelength dependence from the spectrum of the incident light represented by the line L10. When the spectra are plotted to a chromaticity diagram, the result is shown in FIG. 9. The chromaticity coordinates of the background light are (0.330, 0.342); whereas, the chromaticity coordinates of the light transmitted through the color-correcting layers are (0.332, 0.354). The chromaticity diagram shows that there is no significant difference between the transmitted light and the background light, and the transmitted light is within a range of white in the sun light. Hence, on a QLED display including the light-emitting device according to this embodiment, the color tone of the background light does not vary. Note that the integrated intensity of the transmitted light is as low as approximately 28% of the incident light.

Such a configuration achieves the same advantageous effects as those of the first embodiment.

### Fourth Embodiment

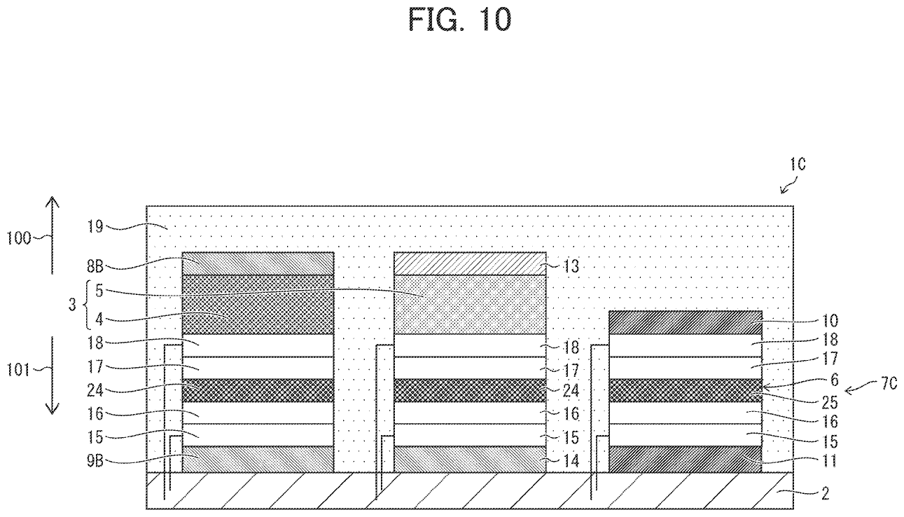

FIG. 10 is a cross-sectional view of a light-emitting device 1C according to a fourth embodiment. Like reference signs denote identical or corresponding constituent features between this embodiment and the previous embodiments. Details of such constituent features will not be elaborated upon here.

The light-emitting device 1C is different from the light-emitting device 1B according to the third embodiment in that the former includes: a near-ultraviolet light-emitting portion 24 that is formed in a position to overlap with the first color-correcting layers 8B and 9B and the third color-correcting layers 13 and 14 in plan view, and that emits a near-ultraviolet light; and a light-emitting layer 7C (the second light-emitting layer) including a blue light-emitting portion 25 that is formed in a position to overlap with the second color-correcting layers 10 and 11 in plan view, and that emits a blue light.

The blue light-emitting portion 25 emits a blue light by electroluminescence. Then, the red light-emitting layer 4 emits a red light by photoluminescence, in accordance with the near-ultraviolet light emitted from the near-ultraviolet light-emitting portion 24 by electroluminescence. The green light-emitting layer 5 emits a green light by photoluminescence, in accordance with the near-ultraviolet light emitted from the near-ultraviolet light-emitting portion 24 by electroluminescence. Hence, the red light-emitting layer 4 and the green light-emitting layer 5 may emit light in accordance with the near-ultraviolet light.

The disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the disclosure. Moreover, the technical aspects disclosed in each embodiment may be combined to achieve a new technical feature.

1. A light-emitting device, comprising:
a substrate transparent to light;
a first light-emitting layer provided above the substrate and containing first quantum dots configured to emit a first light;
a second light-emitting layer provided above the substrate and configured to emit a second light shorter in wavelength than the first light;
a pair of first color-correcting layers each correspondingly provided to one of above or below the first light-emitting layer to overlap with at least a portion of the first light-emitting layer in plan view, transmitting the first light, and absorbing light shorter in wavelength than the first light; and
a pair of second color-correcting layers each correspondingly provided to one of above or below the second light-emitting layer to overlap with the second light-emitting layer in plan view, transmitting the second light, and absorbing light longer in wavelength than the second light.

2. The light-emitting device according to claim 1,
wherein the first light includes a red light and a green light,
the second light includes a blue light,
the first light-emitting layer includes: a red light-emitting layer that emits the red light; and a green light-emitting layer that emits the green light,
the second light-emitting layer includes a blue light-emitting layer that emits the blue light, and
the first color-correcting layers absorb light shorter in wavelength than at least the green light.

3. The light-emitting device according to claim 1 or 2,
wherein the first light-emitting layer is formed in a position to overlap with a portion of the second light-emitting layer in plan view.

4. The light-emitting device according to claim 3,
wherein the second light-emitting layer is separately formed in a position to overlap with the first light-emitting layer in plan view and in a position not to overlap with the first light-emitting layer in plan view.

5. The light-emitting device according to claim 3,
wherein the second light-emitting layer is continuously formed from a position to overlap with the first light-emitting layer in plan view to a position not to overlap with the first light-emitting layer in plan view.

6. The light-emitting device according to claim 1,
wherein the second light-emitting layer emits light by electroluminescence, and
the first light-emitting layer emits light by photoluminescence based on the second light emitted from the second light-emitting layer.

7. The light-emitting device according to claim 1,
wherein the first color-correcting layers transmit the first light emitted from the first light-emitting layer, and absorb the second light emitted toward the first light-emitting layer.

8. The light-emitting device according to claim 2,
wherein the first color-correcting layers transmit the red light emitted from the red light-emitting layer and the green light emitted from the green light-emitting layer, and absorb the blue light emitted toward the red light-emitting layer and the blue light emitted toward the green light-emitting layer.

9. The light-emitting device according to claim 1,
wherein the first light-emitting layer includes: a red light-emitting layer configured to emit a red light; and a green light-emitting layer configured to emit a green light, and
the second light-emitting layer includes: a near-ultraviolet light-emitting portion formed in a position to overlap with the first color-correcting layers in plan view, and configured to emit a near-ultraviolet light; and a blue light-emitting portion formed in a position to overlap with the second color-correcting layers in plan view, and configured to emit a blue light.

10. The light-emitting device according to claim 1,
wherein the second light-emitting layer contains second quantum dots configured to emit the second light.

11. The light-emitting device according to claim 10,
wherein the first color-correcting layers absorb light a wavelength of which is shorter than an absorption edge of the second quantum dots.

12. The light-emitting device according to claim 1,
wherein the first color-correcting layers absorb light having a wavelength of 530 nm or less.

13. The light-emitting device according to claim 1,
wherein, in plan view, the first color-correcting layers are equal in area to the second color-correcting layers.

14. The light-emitting device according to claim 13,
wherein, in plan view, the second light-emitting layer overlapping with the second color-correcting layers is equal in area to the second color-correcting layers.

15. The light-emitting device according to claim 13,
wherein, in plan view, the second color-correcting layers are larger in area than the second light-emitting layer overlapping with the second color-correcting layers.

16. The light-emitting device according to claim 2, further comprising
at least two third color-correcting layers,
wherein the pair of first color-correcting layers overlaps only with the red light-emitting layer in plan view, transmits the red light emitted from the red light-emitting layer, and absorbs light shorter in wavelength than the red light, and
the third color correcting layers each correspondingly provided to one of above or below the green light-emitting layer, overlap only with the green light-emitting layer in plan view, transmit the green light emitted from the green light-emitting layer, and absorb light shorter in wavelength than the green light.

17. The light-emitting device according to claim 16,
wherein the red light-emitting layer contains the first quantum dots,
the green light-emitting layer contains third quantum dots, and
the first color-correcting layers absorb light a wavelength of which is shorter than an absorption edge of the first quantum dots, and the third color-correcting layers absorb light a wavelength of which is shorter than an absorption edge of the third quantum dots.

18. The light-emitting device according to claim 16,
wherein the third color-correcting layers absorb light having a wavelength of 530 nm or less.

19-22. (canceled)

23. The light-emitting device according to claim 1,
wherein the first light-emitting layer emits the first light in a direction toward the substrate and a direction away from the substrate, and
the second light-emitting layer emits the second light in the direction toward the substrate and the direction away from the substrate.

24. The light-emitting device according to claim 1, further comprising
a transparent buffer layer provided above the substrate and disposed side by side with the second light-emitting layer in plan view,
wherein the second color-correcting layers are provided to overlap with the second light-emitting layer and the transparent buffer layer in plan view.
